(19) United States
(12) Patent Application Publication
(10) Pub. No.: US 2022/0330425 A1
(43) Pub. Date: Oct. 13, 2022

(54) MULTI-LAYER MATERIAL WITH ONE OR MORE EMBEDDED FUNCTIONAL LAYERS

(71) Applicant: Uvex Safety Gloves GmbH & Co., KG, Lüneburg (DE)

(72) Inventors: Markus Burghart, Kamenz (DE); Wolfgang Kesting, Bardowick (DE); Matthias Bartusch, Lüneburg (DE)

(73) Assignee: Uvex Safety Gloves GmbH & Co., KG, Lüneburg (DE)

(21) Appl. No.: 17/639,991

(22) PCT Filed: Aug. 28, 2020
(86) PCT No.: PCT/EP2020/074136

§ 371 Date: Mar. 3, 2022

(30) Foreign Application Priority Data
Sep. 4, 2019 (DE) 10 2019 123 664.9

(51) Int. Cl. H05K 1/03; H05K 1/18; H05K 3/00; A41D 19/00

(52) U.S. Cl. CPC H05K 1/038; H05K 1/189; H05K 3/0058; A41D 19/0006; A41D 19/0065; H05K 2201/10151; H05K 2201/05; A41D 2500/10

(57) ABSTRACT

Please replace the current Abstract with the below language:

A multi-layer material comprises a textile substrate layer, a functional layer arranged on the textile substrate layer, and a coating covering the functional layer and the textile substrate. The multi-layer material further includes a textile cover layer arranged between the functional layer and the coating. An adhesive layer is arranged between the functional layer and the textile cover layer. The textile substrate is woven or knitted from one yarn and the textile cover layer is woven or knitted from an identical yarn.

### CROSS REFERENCE TO RELATED INVENTION

This application is a national stage application pursuant to 35 U.S.C. § 371 of International Application No. PCT/EP2020/074136, filed on Aug. 28, 2020, which claims priority to, and benefit of, German Patent Application No. 10 2019 123 664.9, filed Sep. 4, 2019, the entire contents of which are hereby incorporated by reference.

### FIELD OF TECHNOLOGY

The present disclosure relates to a multi-layer material having at least one functional layer and a coating.

### BACKGROUND

In the field of textile coating, it is known to provide textile substrates with a coating, for example a polymer coating. The coating is applied as a coating formulation to the textile substrate, where it can penetrate into the substrate at least in part on account of the porous structure of the substrate. The adhesion of the coating—which is produced, for example, by means of vulcanization—to the substrate is predominantly based on mechanical anchoring.

It is also known to apply functional layers to textile substrates in the form of films, stickers, or printed structures. These functional layers may comprise, in particular, conductor tracks, sensors, or flexible circuit boards. However, it has proven problematic to provide the textile material and accompanying functional layer with another coating, in particular a polymer coating. Although the coating formulation is primarily intended to adhere to the textile substrate particularly well and in a durable manner, there is often insufficient adhesion between the coating and the functional layer.

Two approaches are known for solving the problem of poor adhesion: adapting the coating formulation or adapting the surface of the functional layer.

The coating formulation can be adapted in order to improve adhesion on the functional layer. For this purpose, a majority of the interactions are established on a chemical basis, such that an ionic or covalent bond of the coating to the surface of the functional layer is produced. However, the changes to the composition of the coating formulation also have consequences for properties such as drop time, viscosity, and surface energy, which influence the production process. In addition, the properties of the resulting coating, such as softness, grip, resistance, and visual properties, can also be negatively affected by the changes.

The surface of the functional layer can be adapted to an existing coating formulation by chemical or physical means. The surface of the functional layer can be increased by means of roughening in order to improve mechanical anchoring of the coating. However, in the case of thin functional layers, such as those frequently used in the textile industry, it is not possible to produce internal surfaces on the scale of the textile substrate, and therefore roughening is largely unsuitable.

Chemical adaptation of the surface is aimed at improving the chemical interaction between the functional layer and the coating. However, to do this, the coating formulation must allow for such an interaction, which is simply not the case for chemically resistant coatings, in particular, such as those used in the field of personal protective equipment. In addition, chemical modification can affect the functionality of the elements of the functional layer, as well as their conductivity.

US 2017/0367917 A1 discloses an item of clothing that allows for thermal regulation in different environments. The item of clothing comprises various layers, wherein sensors may also be arranged between the layers.

DE 10 2008 006 969 A1 discloses a glove having a heating means. At least two switches encapsulated in a chamber are provided for setting the temperature. The chamber comprises a flange-like edge that consists of a flexible material.

US 2018/0266900 A1 discloses a pressure sensor comprising conductive fibers, non-conductive fibers, and piezoresistive fibers, which are woven together. The pressure sensor includes a first electrode layer having conductive fibers and non-conductive fibers. A second electrode layer comprises conductive fibers and non-conductive fibers. A piezoresistive layer comprises piezoresistive fibers and is arranged between the first electrode layer and the second electrode layer. It also discloses providing a coating film on an upper and lower face of the pressure sensor.

Proceeding from this, the object of the invention is to provide a multi-layer material—having a textile substrate, a functional layer, and a coating—that features improved adhesion between the functional layer and the coating.

### BRIEF SUMMARY OF THE INVENTION

An embodiment of the multi-layer material according to the invention comprises a textile cover layer, which is arranged between the functional layer and the coating. The multi-layer material is thus composed of a substrate, functional layer, cover layer, and coating. As such, no attempt is made to imitate the surface properties of the textile substrate on the functional layer, but rather a textile cover layer is provided which, like the substrate, allows for partial penetration of the coating formulation on account of its porous structure. As a result, the mechanical anchoring of the coating to the cover layer is comparable to the anchoring of the coating to the textile substrate. Another advantage is that the multi-layer material according to the invention is comfortable to wear. Since functional layers generally are not textile in nature, they are often perceived as bothersome when worn. The textile cover layer provides the functional layer with a feel that corresponds to that of the textile substrate. In addition, the flexibility is affected less by the functional layer than in conventional solutions. The layers, in particular the substrate, functional layer, cover layer, and coating, are each separate layers that are not woven together, linked, interwoven or otherwise connected in a textile manner.

Preferably, the functional layer is in the form of one or more stickers, printed structures, or a combination hereof. The functional layer is flexible and can adapt to possible deformations of the substrate. The textile cover layer does not impair the flexibility of the substrate and of the functional layer.

Preferably, the functional layer comprises conductor tracks, sensors, and/or flexible circuit boards. The sensors may, for example, be pressure sensors, temperature sensors, or current sensors. The measured values of the sensors may be forwarded via conductor tracks.

In order to produce adhesion between the functional layer and the textile substrate, the functional layer is preferably printed, laminated, or glued onto the textile substrate. Particularly preferably, an adhesive layer is additionally arranged between the functional layer and the cover layer in order to produce sufficient cohesion of the multi-layer material. In the simplest case, the adhesive layer is identical to the adhesive layer between the functional layer and the textile substrate. In the field of textiles, hot glues and hot-melt adhesives, among others, are known for this and are applied to the functional layer so as to connect the functional layer to the cover layer under the influence of pressure and temperature. An economically attractive solution is to provide both sides of the functional layer with one adhesive layer each and to glue the layer system consisting of the substrate, functional layer, and cover layer in one step. The adhesive layer may be applied over the entire surface of the functional layer or locally at particular points or in particular regions. Local application of the relevant adhesive layer may be done such that the layers can shift relative to one another, which promotes flexibility of the multi-layer material.

Preferably, the material of the textile substrate is woven or knitted from one yarn. The material obtained in this manner has an open-pore structure that allows for mechanical anchoring of the coating. The textile cover layer preferably consists of a material having similar open-pore surface properties, such that the coating can also be anchored therein. Particularly preferably, the textile cover layer is woven or knitted from the same yarn as the textile substrate. In a particularly simple embodiment, the material of the textile cover layer is identical to the material of the textile substrate. However, it is also conceivable to obtain different materials from the same yarn, for example the substrate may be knitted and the cover layer woven.

Preferably, the coating is a polymer coating, particularly preferably it consists of polyvinyl chloride, nitrile rubber, or polytetrafluoroethylene. The coating formulation, which may contain the polymer components, can be applied by immersing or spraying the textile layers and the embedded functional layer. The textile layers may be pretreated with coagulant in order to regulate the penetration depth of the coating formulation. In further process steps, the coating formulation is vulcanized and the polymer becomes anchored in the porous structure of the textile.

In another embodiment, the textile cover layer completely covers the functional layer. Particularly preferably, the cover layer is larger than the functional layer and can therefore cover the edges of the functional layer and protect against detachment due to acting forces.

In another embodiment of the multi-layer material, the textile cover layer comprises openings in the region of the functional layer. These openings in the cover layer allow for selective coating. In the regions of the openings, the coating is initially in direct contact with the functional layer. However, since the adhesion between the coating and the functional layer is insufficient, the coating can be removed at these points, thus exposing the functional layer in regions.

This produces a particularly preferred embodiment in which the coating comprises openings in the region of the functional layer and these openings coincide with the openings in the textile cover layer. This arrangement allows for access to the exposed regions of the functional layers and to the contacts and sensors arranged therein. As such, information recorded by the sensors can be forwarded and processed further at another location.

Preferably, functional components are arranged on the coating and are in electrically or thermally conductive contact with the functional layer. The conductor tracks or other contacting are guided from the functional layer through the opening in the cover layer and coating to the functional components on the coating. As such, functional components that are not suited for being embedded in the textile layers can be attached to the coating and brought into contact with the functional layer later on.

In an embodiment, an item of personal protective equipment comprises the multi-layer material according to the invention. The multi-layer material according to the invention is particularly suitable for clothing in the field of personal protective equipment, since it is substantially just as comfortable to wear as an item of clothing without a functional layer on account of the textile feel of the embedded functional layer. Furthermore, during processing, the multi-layer material may be treated in the same way as a textile without a functional layer.

In another embodiment, a knitted glove comprises the multi-layer material according to the invention. In this case, the knitted glove blank serves as the textile substrate on which the functional layer and the textile cover layer are applied. The glove blank with the embedded functional layer may be processed further in the same way as a knitted glove without a functional layer.

### BRIEF DESCRIPTION OF THE DRAWINGS

The invention will be explained in more detail in the following based on embodiments shown in the figures, in which:

FIG. 1 illustrates a cross-sectional view through an embodiment of a multi-layer system;

FIG. 2 illustrates a plan view of an embodiment of a multi-layer system having an opening in the region of the functional layer and functional components on the coating; and

FIG. 3 illustrates a cross-section through the embodiment of FIG. 2.

### DETAILED DESCRIPTION OF THE INVENTION

FIG. 1 is a cross-section through a multi-layer system without a coating. It shows the textile substrate 1 and the functional layer 2 fixed thereon. An adhesive layer 3 is shown between the cover layer 4 and the functional layer 2. The adhesive layer 3 may comprise a hot glue or hot-melt adhesive that becomes connected to the cover layer 4 and functional layer 2 under the influence of pressure and heat.

The cover layer 4 shown extends beyond the functional layer 2, such that the cover layer 4 overlaps with the edges of the functional layer 2. This overlap protects the functional layer 2 against locally applied forces that could facilitate detachment of the functional layer 2 from the textile substrate 1.

In the figure, the cover layer 4 is shown thinner than the substrate. Regardless of the thickness, both layers can be produced from the same yarn.

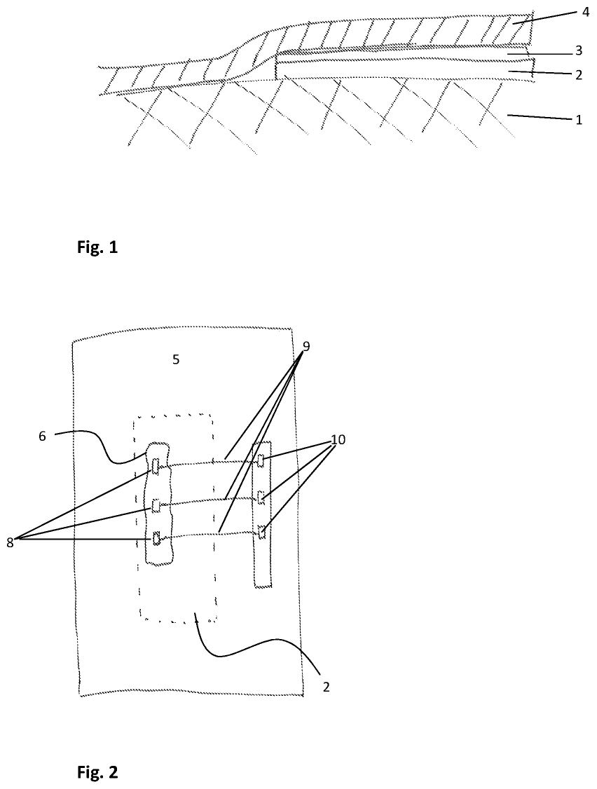

FIG. 2 is a plan view of an exemplary embodiment of a multi-layer material having openings 6 in the cover layer 4 and coating 5. The functional layer 2 underneath the coating 5 is indicated by means of a hatched line. The openings 6 overlap and expose part of the underlying functional layer 2. In the exemplary embodiment shown, multiple contacts 8 located on the functional layer 2 are exposed. The elements of the functional layer 2 are connected via conductor tracks 9 to functional components 10 that are located on the coating 5. The functional components may be sensors or the like.

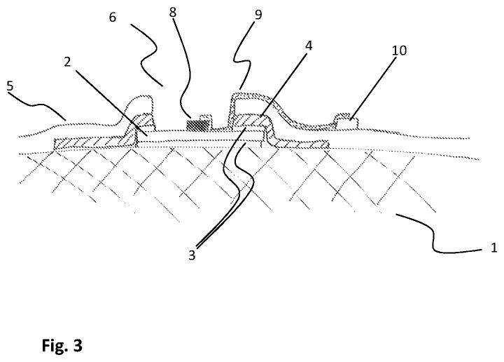

FIG. 3 is a cross-section through the system shown in FIG. 2. The functional layer 2 has been applied to the textile substrate 1. The functional layer 2 is glued to the substrate 1 by means of an adhesive layer 3. The cover layer 4 extends over the functional layer 2 and beyond the edges of the functional layer 2. The cover layer 4 comprises an opening 6 that exposes a contact 8 on the functional layer 2. The coating 5 has an opening at the same point. A conductor track 9 leads from the contact 8 to a functional component 10 that is arranged on the coating close to the opening.

The problem addressed by the invention can be explained well in technical terms based on the following example. A glove that is, for example, knitted without seams and that substantially consists of polyamide and spandex yarns forms the textile substrate. A functional layer is laminated onto said textile substrate in the region of the palm by means of a hot-pressing method. The functional layer consists of an elastic carrier film made of thermoplastic PU (TPU) and also consists of printed conductor tracks and sensor structures on the upper face.

Subsequently, the glove with the functional layer is coated with a nitrile layer. For this purpose, the glove is pulled onto a mold and immersed in a saline solution, which coagulates in contact with the salt. After coagulation, the glove is washed to remove the excess salt. Subsequently, the glove is dried and the nitrile coating vulcanizes completely.

The finished glove exhibits significantly poorer adhesion of the nitrile coating on the functional layer compared with the textile substrate. This poorer adhesion is evidenced by run-off marks and detachment of the nitrile coating from the functional layer. The abrasion test according to DIN EN 388 shows complete detachment of the nitrile layer from the TPU after less than 200 cycles.

In the solution according to the invention, the functional layer consisting of TPU with its conductor tracks is sprayed on the upper face with a layer of adhesive prior to lamination and a cover layer consisting of a knitted polyamide and spandex fabric is applied thereto.

Subsequently, the functional layer and the cover layer applied thereto are laminated onto the textile substrate as in the previous example. Then, the coating with nitrile takes place.

The gloves do not exhibit any visual differences between the coating on the textile substrate and the functional layer. Only the difference in thickness is evident from the additional layer formed by the cover layer. The abrasion test according to DIN EN 388 reaches more than 8,000 cycles in the region of the cover layer and in the region of the textile substrate.

In another embodiment, a polyamide fiber layer with an average fiber length of 0.5 mm is applied as the cover layer. At this length, the fibers are referred to as short fibers. During lamination of the functional layer, the short fibers on the upper face of the functional layer are partially pressed in. The corresponding regions are fibers that are sunk in at different depths and thus produce an inhomogeneous coating look for the cover layer. It should be noted that fibers that have not been pressed in as far provide better adhesion for the nitrile coating. The abrasion test according to DIN EN 388 thereby reaches between 500 and 2,000 cycles in the region of the cover layer before the nitrile and cover layer are worn through.

In another embodiment, an elastic woven fabric consisting of viscose and spandex is applied as the cover layer to the upper face of the functional layer. The woven fabric is provided with a thermally activatable layer of adhesive on its lower face. The layer of adhesive is not sprayed on. In this example, the textile substrate, the functional layer, and the cover layer can be laminated in a joint step.

In these examples, visual defects can be seen in the form of air bubbles, which are caused by the viscose fibers not being sufficiently wetted with saline solution. Accordingly, the nitrile dispersion coagulates in an inhomogeneous manner and with little penetration in the region of the cover layer. The abrasion test according to DIN EN 388 reaches 2,000 cycles in the region of the cover layer before the nitrile and cover layer are worn through.

List of Reference Signs

1 Textile substrate

2 Functional layer

3 Adhesive layer

4 Cover layer

5 Coating

6 Opening

8 Contact

9 Conductor track

10 Functional component

claims

1

-

13

canceled.

14. A multi-layer material comprising:
a textile substrate layer;
a functional layer arranged on the textile substrate layer;
a coating covering the functional layer and the textile substrate;
a textile cover layer is arranged between the functional layer and the coating; and
an adhesive layer arranged between the functional layer and the textile cover layer, wherein the textile substrate layer is woven or knitted from one yarn and the textile cover layer is woven or knitted from an identical yarn.

15. The multi-layer material according to claim 14, wherein the functional layer comprises at least one of: (1) a sticker; and (2) a printed structure.

16. The multi-layer material according to claim 14, wherein the functional layer comprises at least one of: (1) conductor tracks; (2) sensors; and (3) flexible circuit boards.

17. The multi-layer material according to claim 14, wherein the functional layer is printed onto the textile substrate layer.

18. The multi-layer material according to claim 14, wherein the functional layer is laminated onto the textile substrate layer.

19. The multi-layer material according to claim 14, wherein the functional layer is glued onto the textile substrate layer.

20. The multi-layer material according to claim 14, wherein the coating is a polymer coating.

21. The multi-layer material according to claim 20, wherein the polymer coating comprises one of: (1) polyvinyl chloride; (2) nitrile rubber; and (3) polytetrafluoroethylene.

22. The multi-layer material according to claim 14, wherein the textile cover layer completely covers the functional layer .

23. The multi-layer material according to claim 14, wherein the textile cover layer comprises a plurality of openings in a region over the functional layer.

24. The multi-layer material according to claim 23, wherein the coating comprises a plurality of openings that correspond with the plurality of openings in the textile cover layer.

25. The multi-layer material according to claim 23, further comprising functional components arranged on the coating, wherein the functional components are in electrical contact with the functional layer.

26. The multi-layer material according to claim 23, further comprising functional components arranged on the coating, wherein the functional components are in thermally conductive contact with the functional layer.

27. The multi-layer material according to claim 14, wherein the multi-layer material is formed into a piece of personal protective equipment.

28. A knitted glove comprising:
a multilayer material that comprises,
a textile substrate layer;
a functional layer arranged on the textile substrate layer;
a coating covering the functional layer and the textile substrate;
a textile cover layer is arranged between the functional layer and the coating; and
an adhesive layer arranged between the functional layer and the textile cover layer,
wherein the textile substrate layer is woven or knitted from one yarn and the textile cover layer is woven or knitted from an identical yarn, and
wherein the multilayer material is formed as a glove.
